(19) United States
(12) Patent Application Publication
(10) Pub. No.: US 2011/0260297 A1
(43) Pub. Date: Oct. 27, 2011

(54) THROUGH-SUBSTRATE VIA AND FABRICATION METHOD THEREOF

(76) Inventors: Shian-Jyh Lin, Taipei County (TW); Shing-Hwa Renn, Taipei City (TW)

(21) Appl. No.: 12/767,808

(22) Filed: Apr. 27, 2010

(51) Int. Cl. H01L 23/48; H01L 21/768

(52) U.S. Cl. 257/621; 438/612; 438/675; 257/E21.597; 257/E23.011

(57) ABSTRACT

A method for fabricating a through-substrate via structure. A semiconductor substrate is provided. A first via hole is etched into the semiconductor substrate. A spacer is formed on sidewall of the first via hole. The semiconductor substrate is etched through the first via hole to form a second via hole. The second via hole is wet etched to form a bottle-shaped via hole. An insulating layer is formed lining a lower portion of the bottle-shaped via hole. A first conductive layer is deposited within the bottle-shaped via hole, wherein the first conductive layer define a cavity. A bond pad is formed on a front side of the semiconductor substrate, wherein the bond pad is electrically connected with the first conductive layer. A back side of the semiconductor substrate is polished to reveal the cavity. The cavity is filled with a second conductive layer.

### BACKGROUND OF THE INVENTION

1. Field of the Invention

The present invention relates generally to semiconductor technology, and more particularly to a through-substrate via or through-silicon via (TSV) for connection of stacked chips and a method for forming the same.

2. Description of the Prior Art

Packaging technology for an integrated circuit has continuously been developed to meet the demand toward miniaturization and mounting reliability. As known in the art, stack package is a vertical stand or pile of at least two chips or packages, one atop the other. By using a stack, in the case of a memory device for example, it is possible to produce a product having a memory capacity which is two times greater than that obtainable through semiconductor integration processes.

A stack package provides advantages not only through an increase in memory capacity but also in view of a mounting density and mounting area utilization efficiency. As an example of a stack package, a through-substrate via or through-silicon via (TSV) has been disclosed in the art. The stack package using a TSV has a structure in which the TSV is formed in a chip so that chips are physically and electrically connected with each other through the TSV.

Through-substrate via is typically fabricated to provide the through-via filled with a conducting material that pass completely through the silicon substrate layer to contact and connect with the other TSVs and conductors of the bonded layers.

For example, a vertical hole is defined through a predetermined portion of each chip at a wafer level. An insulation layer is formed on the surface of the vertical hole. With a seed metal layer formed on the insulation layer, a metal is filled into the vertical hole through an electroplating process to form a TSV. Then, the TSV is exposed through back-grinding of the backside of a wafer. After the wafer is sawed and is separated into individual chips, at least two chips can be vertically stacked, one atop the other, on one of the substrates using one or more of the TSV. Thereupon, the upper surface of the substrate including the stacked chips is molded, and solder balls are mounted on the lower surface of the substrate.

However, the TSV process faces challenges when using conventional chemical vapor deposition (CVD) methods to fill 10 μm via hole. Further, large size via hole suffers from low throughput when depositing films into the via hole. Therefore, there is a need in this industry to provide an improved TSV process in order to cope with these prior art problems and shortcomings.

### SUMMARY OF THE INVENTION

The present invention is directed to a through-substrate via which can improve overlay accuracy in the manufacture of a stack package using the TSV, and a method for forming the same.

In one aspect, the claimed invention discloses a method for fabricating a through-substrate via structure, which includes providing a semiconductor substrate having thereon an interlayer dielectric; etching a first via hole into the interlayer dielectric and the semiconductor substrate; forming a spacer on sidewall of the first via hole; etching the semiconductor substrate through the first via hole, thereby forming a second via hole; widening the second via hole, thereby forming a bottle-shaped via hole; forming an insulating layer on interior surface of a lower portion of the bottle-shaped via hole; depositing a first conductive layer within the bottle-shaped via hole, wherein the first conductive layer define a cavity at the lower portion of the bottle-shaped via hole; forming a bond pad on a front side of the semiconductor substrate, wherein the bond pad is electrically connected with the first conductive layer; grinding a back side of the semiconductor substrate to reveal the cavity; and filling the cavity with a second conductive layer from the back side of the semiconductor substrate.

In another aspect, the claimed invention discloses a method for fabricating a through-substrate via structure, which includes providing a semiconductor substrate having thereon an interlayer dielectric; etching a plurality of first via holes arranged in proximity to each other into the interlayer dielectric and the semiconductor substrate; forming a spacer on sidewall of the first via holes; etching the semiconductor substrate through the first via holes to thereby form second via holes; widening the second via holes, thereby forming a bottle-shaped via hole; forming an insulating layer on the semiconductor substrate within the bottle-shaped via hole; depositing a first conductive layer within the bottle-shaped via hole, wherein the first conductive layer define a cavity at a lower portion of the bottle-shaped via hole; forming a bond pad on a front side of the semiconductor substrate, wherein the bond pad is electrically connected with the first conductive layer; grinding a back side of the semiconductor substrate to reveal the cavity; and filling the cavity with a second conductive layer from the back side of the semiconductor substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-8 are schematic, cross-sectional diagrams showing a method for fabricating a through-substrate via or through-silicon via (TSV) structure for connection of stacked chips in accordance with one preferred embodiment of this invention;

FIG. 9 is an exemplary top view of the cluster of hole patterns of the photoresist pattern that defines the through-substrate via in accordance with the preferred embodiment of this invention;

FIG. 10 is an exemplary top view of the photoresist pattern that defines the through-substrate via in accordance with another embodiment of this invention; and

FIG. 11 is an exemplary top view of the photoresist pattern that defines the through-substrate via in accordance with still another embodiment of this invention.

It should be noted that all the Figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. However, it will be apparent to one skilled in the art that the invention may be practiced without these specific details. In order to avoid obscuring the present invention, some well-known system configurations and process steps are not disclosed in detail. The drawings showing embodiments of the apparatus are semi-diagrammatic and not to scale and, particularly, some of the dimensions are for the clarity of presentation and are shown exaggerated in the figures.

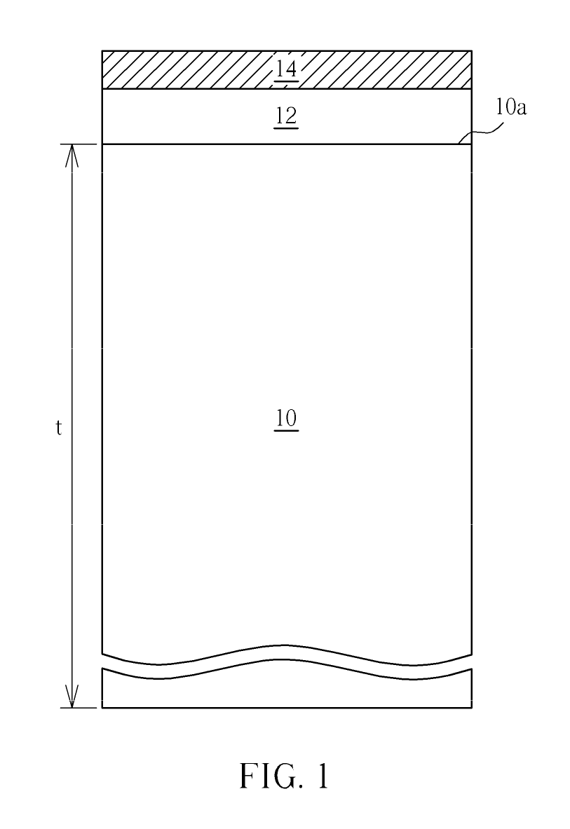

Please refer to FIGS. 1-8. FIGS. 1-8 are schematic, cross-sectional diagrams showing a method for fabricating a through-substrate via structure for connection of stacked chips in accordance with one preferred embodiment of this invention. As shown in FIG. 1, a semiconductor substrate 10 is provided. The semiconductor substrate 10 may be a silicon substrate, for example. However, it is understood that the semiconductor substrate 10 may be any other substrates such as a silicon substrate with an epitaxial layer, a silicon-on-insulator substrate containing a buried insulator layer, gallium arsenide (GaAs) substrate, gallium arsenide-phosphide (GaAsP) substrate, indium phosphide (InP) substrate, gallium aluminum arsenic (GaAlAs) substrate, or indium gallium phosphide (InGaP) substrate. A plurality of circuit components (not shown) such as transistors capacitors may be fabricated on the main surface 10a of the semiconductor substrate 10. Typically, the semiconductor substrate 10 has thickness t of about 760 micrometers (for 300 mm wafer). An interlayer dielectric 12 is provided on the main surface 10a of the semiconductor substrate 10. The interlayer dielectric 12 may be a single layer or a multi-layered structure. An interconnection structure (not shown) may be formed in the interlayer dielectric 12. A hard mask layer 14 such as carbon, bottom anti-reflection materials, metal or combination thereof may be formed on the interlayer dielectric 12.

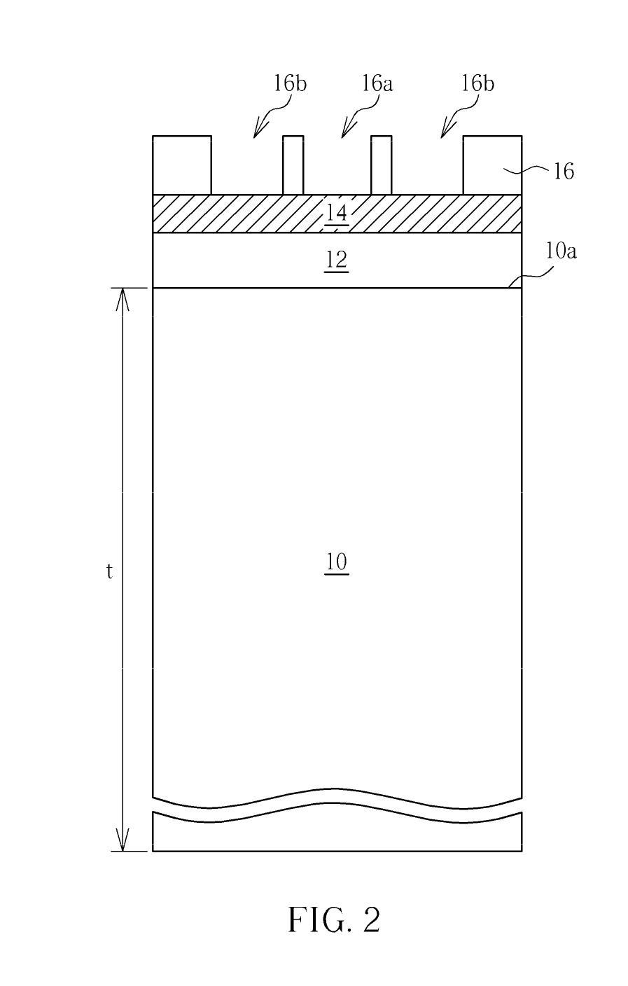

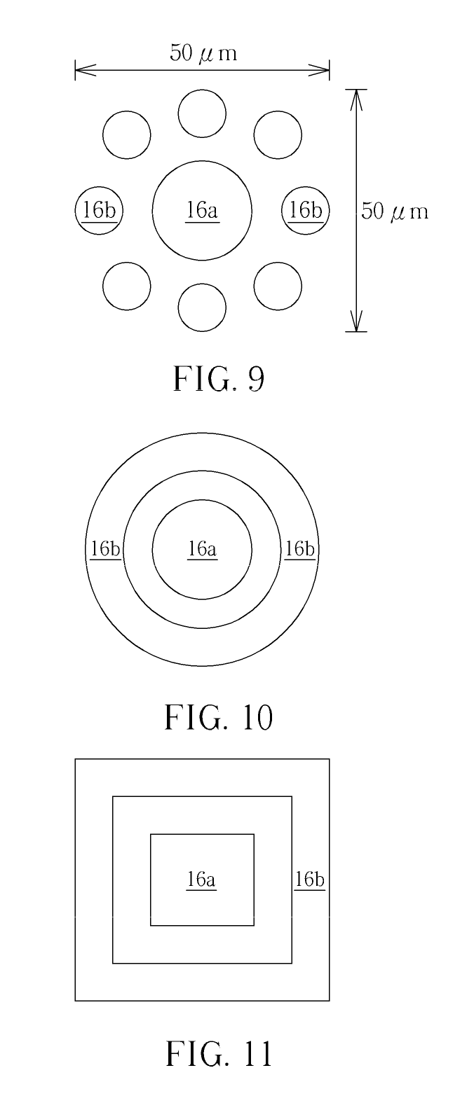

As shown in FIG. 2, a photoresist pattern 16 is formed on the hard mask layer 14. According to the preferred embodiment, the photoresist pattern 16 comprises a cluster of hole patterns including a central hole pattern 16a and a plurality of subsidiary hole patterns 16b surrounding the central hole pattern 16a. An exemplary top view of the cluster of hole patterns of the photoresist pattern 16 is illustrated in FIG. 9. According to the preferred embodiment, the dimension of the cluster of hole patterns may be about 50 μm×50 μm or smaller. In one embodiment of this invention, as illustrated in FIG. 10, the photoresist pattern 16 may comprise a central hole pattern 16a and an annular hole pattern 16b surrounding the central hole pattern 16a. In another embodiment of this invention, as illustrated in FIG. 11, the photoresist pattern 16 may comprise a rectangular central hole pattern 16a and a rectangular annular hole pattern 16b surrounding the central hole pattern 16a.

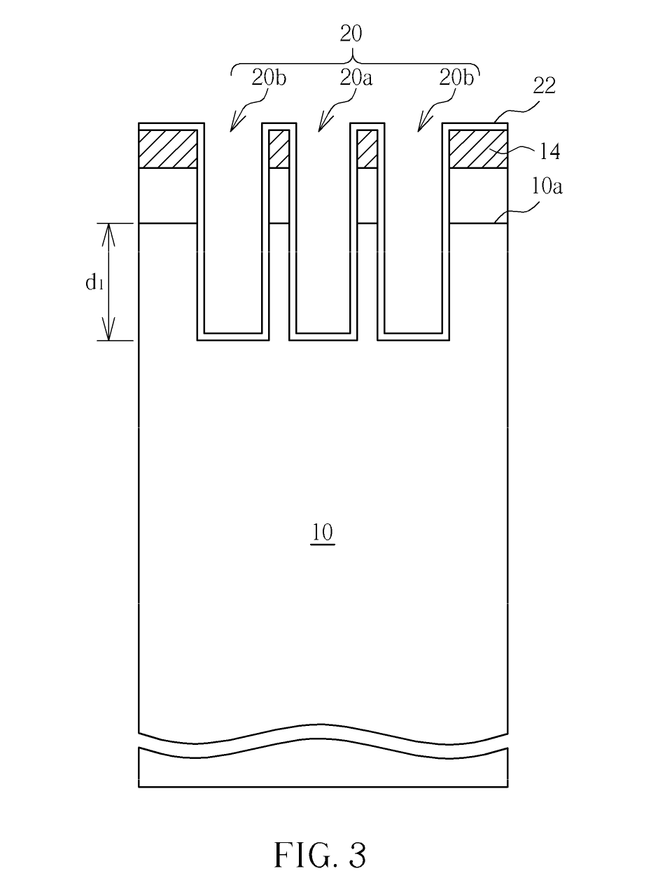

As shown in FIG. 3, using the photoresist pattern 16 as an etching mask, a dry etching process is then carried out to form a plurality of via holes 20 including a central via hole 20a and a plurality of subsidiary via holes 20b that pass through the interlayer dielectric 12 and extend to reach a predetermined depth d1 of the semiconductor substrate 10. The patterned photoresist layer 16 is then stripped. According to the preferred embodiment, preferably, the predetermined depth d1 below the main surface of the semiconductor substrate 10 is less than 5 micrometers. Subsequently, a spacer material layer 22 is conformally deposited on the semiconductor substrate 10 to line the sidewalls and bottom of the via holes 20. According to the preferred embodiment, the spacer material layer 22 is made of dielectric material having high etching selectivity with respect to the semiconductor substrate 10. Preferably, the spacer material layer 22 may be formed of silicon nitride. The spacer material layer 22 also covers the top surface of the hard mask layer 14.

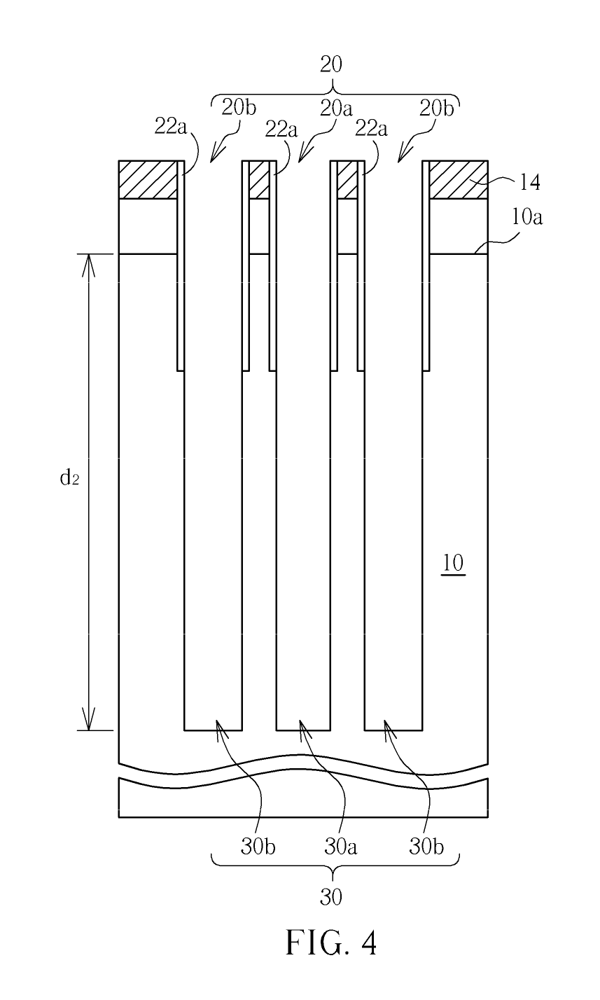

As shown in FIG. 4, after the deposition of the spacer material layer 22, an anisotropic dry etching process is then carried out to etch the spacer material layer 22 and the semiconductor substrate 10 through the via holes 20, thereby forming deep via holes 30 including a central deep via hole 30a and a plurality of subsidiary deep via holes 30b underneath via holes 20 respectively. At this point, a spacer 22a is formed on each sidewall of the via holes 20. According to the preferred embodiment, for example, the predetermined depth d2 below the main surface of the semiconductor substrate 10 is less than 53 micrometers.

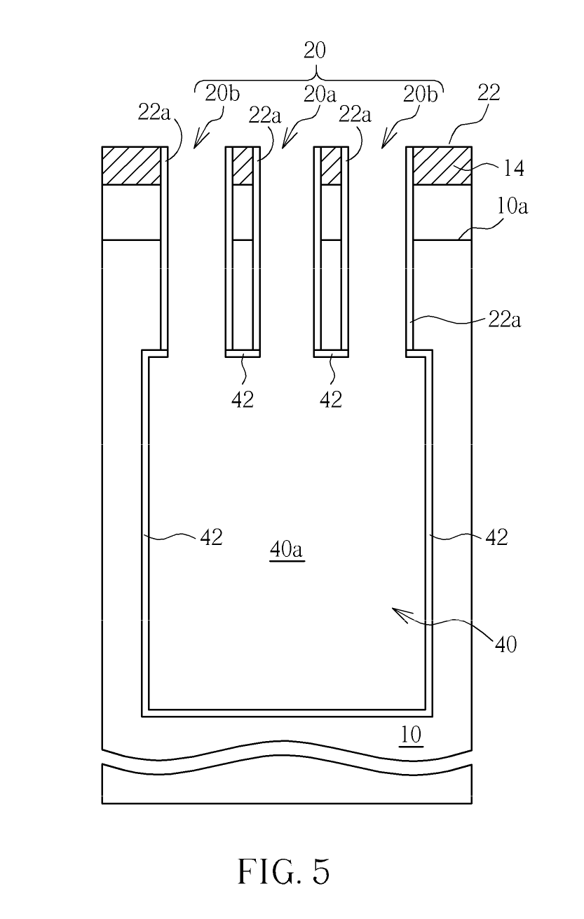

As shown in FIG. 5, an etching process is carried out to etch the sidewall of the semiconductor substrate 10 under the spacer through the deep via holes 30. Since the central deep via hole 30a and a plurality of subsidiary deep via holes 30b are arranged in close proximity to each other, the widened central deep via hole 30a and the widened subsidiary deep via holes 30b will merge together eventually, thereby forming a merged bottle-shaped via hole 40 including the central via hole 20a and the subsidiary via holes 20b overlying the lower merged chamber 40a. According to the preferred embodiment, the aforesaid etching process may be carried out with a diluted ammonia solution, wherein the ratio of concentrated ammonia water:water is preferably 1:5-1:50. Subsequently, an oxidation process is carried out to form a silicon oxide layer 42 on the interior surface of the lower merged chamber 40a of the bottle-shaped via hole 40.

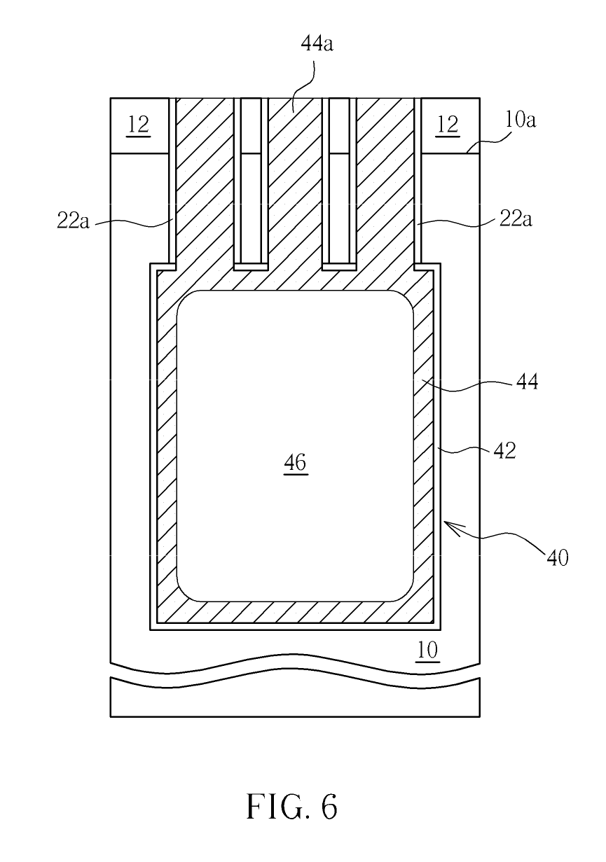

As shown in FIG. 6, after the formation of the silicon oxide layer 42, a chemical vapor deposition (CVD) process is carried out to conformally deposit a first conductive layer 44 such as tungsten on the interior surface of the lower portion of the bottle-shaped via hole. In one embodiment, the first conductive layer 44 may be composed of composite metal layer including but not limited to TiN/W, TaN/W, TiN/TaN or WN/W, which can be formed by CVD, PVD or ALD methods. In one embodiment, the first conductive layer 44 may be composed of polysilicon. According to the preferred embodiment, the first conductive layer 44 seals the via holes 20 to form conductive plugs 44a in the via holes 20. According to the preferred embodiment, the first conductive layer 44 define a cavity 46 at the lower portion of the bottle-shaped via hole 40. The hard mask layer 14 and a portion of the first conductive layer 44 overlying the interlayer dielectric 12 may be removed by etching or polishing methods, for example, chemical mechanical polishing (CMP).

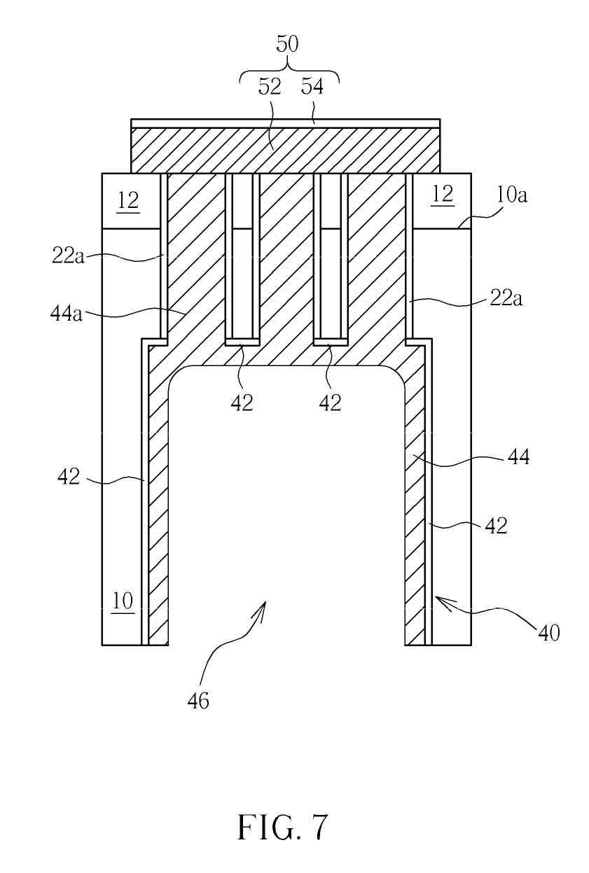

As shown in FIG. 7, a bond pad 50 may be formed on the conductive plugs 44a. In other embodiments, the bond pad 50 may be electrically connected with the conductive plugs 44a through other metal layers. The bond pad 50 may includes but not limited to a bondable metal layer 52 and a glue layer 54. According to the preferred embodiment, the bondable metal layer 52 directly contacts with the conductive plugs 44a. Subsequently, a wafer back side grinding process is carried out to polish the back side of the semiconductor substrate 10. As previously mentioned, the thickness t of the semiconductor substrate 10 before grinding is typically about 760 micrometers for 300 mm wafer. After the wafer back side grinding, the remaining thickness of the semiconductor substrate 10 may be about 50 micrometers or less than 50 micrometers. At this point, after the wafer back side grinding is completed, the bottom portion of the conductive layer 44 as well as the silicon oxide layer 42 at the bottom of the bottle-shaped via hole 40 are removed, thereby revealing the cavity 46.

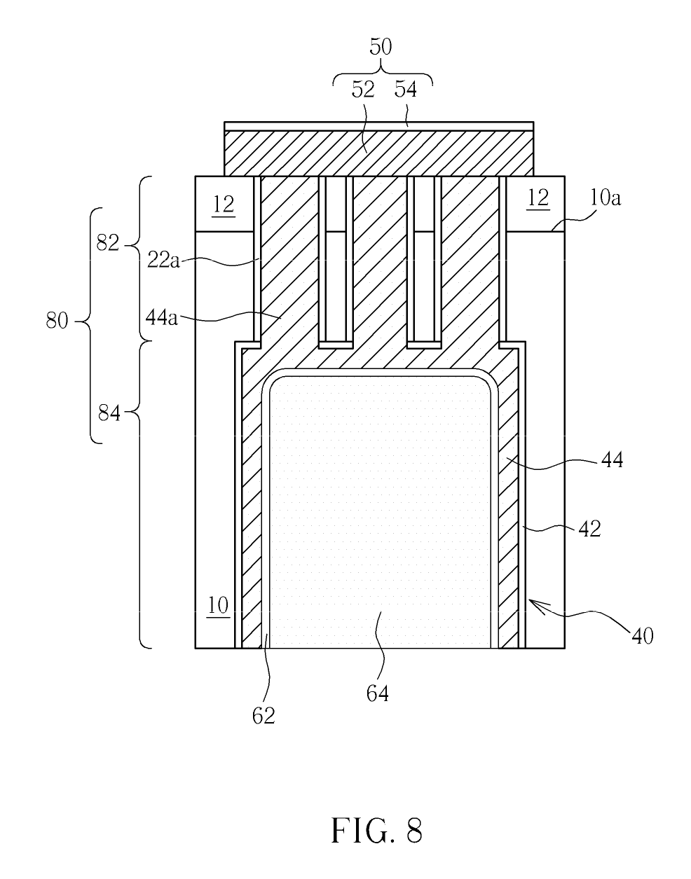

As shown in FIG. 8, thereafter, a seed layer 62 such as a copper seed layer is deposited on the interior surface of the cavity 46, more specifically, on the surface of the first conductive layer 44. Subsequently, a second conductive layer 64 is formed. For example, the second conductive layer 64 is copper layer and a copper plating process may be carried out to deposit the copper layer on the seed layer 62. According to the preferred embodiment, the copper layer 64 fills the cavity 46 and covers the wafer backside. The aforesaid copper layer 64 may be formed by electroplating, electroless plating, chemical plating or any suitable methods known in the art. The copper layer 64 outside the cavity 46 may be removed by conventional CMP process. After the removal of the wafer backside copper, the fabrication of the through-substrate via 80 is complete. It is advantageous to use the present invention because the first conductive layer 44 such as tungsten has coefficient of thermal expansion (CTE) that matches or nearly matches that of the silicon such that a less-stressed TSV can be formed. From one aspect of the invention, the through-substrate via 80 comprises a first half portion 82 and a second half portion 84. The first half portion 82 comprises the conductive plugs 44a. The second half portion 84 comprises the first conductive layer 44, the copper seed layer 62 and the copper layer 64. The second half portion 84 contacts with the first half portion 82. The second half portion 84 extends from a bottom of the first half portion to the wafer backside.

Those skilled in the art will readily observe that numerous modifications and alterations of the device and method may be made while retaining the teachings of the invention.

What is claimed is:

1. A method for fabricating a through-substrate via structure, comprising:
providing a semiconductor substrate having thereon an interlayer dielectric;
etching a first via hole into the interlayer dielectric and the semiconductor substrate;
forming a spacer on sidewall of the first via hole;
etching the semiconductor substrate through the first via hole, thereby forming a second via hole;
widening the second via hole, thereby forming a bottle-shaped via hole;
forming an insulating layer on interior surface of a lower portion of the bottle-shaped via hole;
depositing a first conductive layer within the bottle-shaped via hole, wherein the first conductive layer define a cavity at the lower portion of the bottle-shaped via hole;
forming a bond pad on a front side of the semiconductor substrate, wherein the bond pad is electrically connected with the first conductive layer;
grinding a back side of the semiconductor substrate to reveal the cavity; and
filling the cavity with a second conductive layer from the back side of the semiconductor substrate.

2. The method for fabricating a through-substrate via structure according to claim 1 wherein the spacer is made of material having high etching selectivity with respect to the semiconductor substrate.

3. The method for fabricating a through-substrate via structure according to claim 1 wherein the insulating layer comprises a silicon oxide layer.

4. The method for fabricating a through-substrate via structure according to claim 3 wherein the silicon oxide layer is formed by thermal oxidation method, CVD or ALD.

5. The method for fabricating a through-substrate via structure according to claim 3 wherein the silicon oxide layer is formed on exposed surface of the semiconductor substrate not covered by the spacer within the second via hole.

6. The method for fabricating a through-substrate via structure according to claim 1 wherein the insulating layer does not fill up the bottle-shaped via hole.

7. The method for fabricating a through-substrate via structure according to claim 1 wherein the first conductive layer comprises tungsten, WN, TiN, TaN or polysilicon.

8. The method for fabricating a through-substrate via structure according to claim 1 wherein the first conductive layer seals the first via hole.

9. The method for fabricating a through-substrate via structure according to claim 8 wherein the first conductive layer is conformally deposited on the interior surface of the lower portion of the bottle-shaped via hole.

10. The method for fabricating a through-substrate via structure according to claim 1 wherein the second conductive layer comprises copper.

11. A method for fabricating a through-substrate via structure, comprising:
providing a semiconductor substrate having thereon an interlayer dielectric;
etching a plurality of first via holes arranged in proximity to each other into the interlayer dielectric and the semiconductor substrate;
forming a spacer on sidewall of the first via holes;
etching the semiconductor substrate through the first via holes to thereby form second via holes;
widening the second via holes, thereby forming a bottle-shaped via hole;
forming an insulating layer on the semiconductor substrate within the bottle-shaped via hole;
depositing a first conductive layer within the bottle-shaped via hole, wherein the first conductive layer define a cavity at a lower portion of the bottle-shaped via hole;
forming a bond pad on a front side of the semiconductor substrate, wherein the bond pad is electrically connected with the first conductive layer;
grinding a back side of the semiconductor substrate to reveal the cavity; and
filling the cavity with a second conductive layer from the back side of the semiconductor substrate.

12. The method for fabricating a through-substrate via structure according to claim 11 wherein the plurality of first via holes comprises a central via hole and a plurality of subsidiary via holes surrounding the central via hole.

13. The method for fabricating a through-substrate via structure according to claim 11 wherein the plurality of first via holes comprises a central via hole and an annular via hole encompassing the central via hole.

14. The method for fabricating a through-substrate via structure according to claim 11 wherein the spacer is made of material having high etching selectivity with respect to the semiconductor substrate.

15. The method for fabricating a through-substrate via structure according to claim 11 wherein the insulating layer is a silicon oxide layer.

16. The method for fabricating a through-substrate via structure according to claim 15 wherein the silicon oxide layer is formed by thermal oxidation method, CVD or ALD.

17. The method for fabricating a through-substrate via structure according to claim 15 wherein the silicon oxide layer is formed on exposed surface of the semiconductor substrate not covered by the spacer within the second via hole.

18. The method for fabricating a through-substrate via structure according to claim 11 wherein the insulating layer does not fill up the bottle-shaped via hole.

19. The method for fabricating a through-substrate via structure according to claim 11 wherein the first conductive layer comprises tungsten, WN, TiN, TaN or polysilicon.

20. The method for fabricating a through-substrate via structure according to claim 11 wherein the first conductive layer seals the first via hole.

21. The method for fabricating a through-substrate via structure according to claim 20 wherein the first conductive layer is conformally deposited on the interior surface of the lower portion of the bottle-shaped via hole.

22. The method for fabricating a through-substrate via structure according to claim 11 wherein the second conductive layer comprises copper.

23. A through-substrate via structure, comprising:
a first half portion extending from a first side of a substrate into a prescribed depth of the semiconductor substrate;
a second half portion contacting the first half portion and extending from a bottom of the first half portion to a second side of the substrate; and
a liner film lining between the first and second half portions and the substrate.

24. The through-substrate via structure according to claim 23 wherein the first half portion comprises a conductive plug made out of tungsten.

25. The through-substrate via structure according to claim 23 wherein second half portion comprises a tungsten layer enclosing a copper layer.
